(19) United States
(12) Patent Application Publication
(10) Pub. No.: US 2003/0111438 A1
(43) Pub. Date: Jun. 19, 2003

(54) Process operation supplementation with oxygen

(76) Inventors: Kevin M. Mukai, Santa Clara, CA (US); Shankar Chandran, San Jose, CA (US)

Correspondence Address: APPLIED MATERIALS, INC., 2881 SCOTT BLVD. M/S 2061, SANTA CLARA, CA, 95050, US

(21) Appl. No.: 10/025,442

(22) Filed: Dec. 18, 2001

(51) Int. Cl. H01L 21/306; C23C 16/00

(52) U.S. Cl. 216/2; 216/68; 216/63; 156/345.24; 156/345.29; 700/121; 118/696; 118/697; 118/715

(57) ABSTRACT

A method including in a wafer processing environment, introducing a liquid via a carrier gas, and separate from the liquid, introducing a first gas comprising ozone and a legacy amount of oxygen and a second gas comprising an effective amount of oxygen to modify a process operation. A system including a chamber, a liquid source, a first gas source, and a second gas source, a controller configured to control the introduction into the chamber of a liquid from the liquid source, a first gas comprising ozone and a legacy amount of oxygen from the first source, a second gas comprising oxygen from the second gas source, and a memory coupled to the controller comprising a machine-readable medium having a program embodied therein for controlling the second gas to introduce an effective amount of oxygen into the chamber to modify a process operation.

### BACKGROUND

1. Field of the Invention

The invention relates to microelectronic structure fabrication.

2. Background

In the fabrication of modem microelectronic structures, such as microprocessor and memory structures, oxidation processes are used to passivate or oxidize a substrate or film, such as semiconductor substrates or films. Typical methods of passivation of silicon surfaces and films, such as for example, polycrystalline silicon gate electrodes and silicon substrates, include oxygen (O₂) and water vapor or steam oxidation processes.

Oxide (e.g., silicon dioxide (SiO₂) films are also often used to electrically isolate one device from another in a circuit structure and one level of conductor from another in multi-level interconnect systems such as found in many microelectronic structures. A microprocessor, for example, may have five or more levels of interconnect over a substrate such as a semiconductor substrate. Typical oxide film material includes undoped silicate glass (USG), borosilicate glass (BSG), phosphosilicate glass (PSG), and borophosphosilicate glass (BPSG).

Chemical vapor deposition (CVD) is a typical process for introducing (e.g., depositing) various types of films on substrates and is used extensively in the fabrication of microelectronic structures. In a typical CVD process, a wafer or wafers are placed in a deposition or reaction chamber and reactant gases are introduced into the chamber and are decomposed and combined or reacted at a heated surface to form a film on the wafer or wafers.

One example of a CVD film formation process involves the introduction of a liquid, such as tetraethylorthosilicate (TEOS), tetraethylborosilicate (TEB), or tetraethylphosphosilicate (TEPO) into a deposition chamber. Such liquids may be introduced with a carrier gas such as helium (He), nitrogen (N₂), or a combination of helium and nitrogen. The liquid is injected into the carrier gas and carried to the chamber through what is representatively referred to as a liquid line. At the same time, ozone (O₃) is introduced to the chamber through what is representatively referred to as a gas line. Prior to entering the chamber, the contents of the gas line and the contents of the liquid line may be mixed in, for example, a mixing block. The mixture is then introduced into the chamber.

One way to form ozone is by exposing oxygen to an energy source (e.g., electrical discharge or ultraviolet light) in an ozonator. Typically, for a given amount of oxygen introduced into an ozonator, the ozonator will have a discharge of ozone with a legacy amount of oxygen.

One goal of any film formation process is to attempt to improve the film properties. Such film properties may include introduction (e.g., deposition) rate, uniformity, moisture absorption, shrinkage, index of refraction, gap fill and electrical properties as well as dopant concentrations and levels.

### SUMMARY

In one embodiment, a method is described. One example of the method includes, in a wafer processing environment, introducing a liquid via a carrier gas and, separate from the liquid, introducing a gas. The gas includes a first gas comprising ozone and a legacy amount of oxygen and a second gas comprising an effective amount of oxygen to modify a process operation. The second gas comprising an effective amount of oxygen supplements the ozone source and, in combination with the liquid, provides improved properties with regard to film formation or etch characteristic.

In another embodiment, a system is disclosed. The system includes a chamber, a liquid source coupled to the chamber, and a first and second gas source coupled to the chamber. A system controller is configured to control the introduction into the chamber of a liquid from the liquid source, a first gas comprising ozone and the legacy amount of oxygen from the first gas source, and a second gas comprising oxygen from the second gas source. The system further includes a memory coupled to the controller comprising a machine-readable medium having a machine-readable program embodied therein for directing operation of the system. The machine-readable program comprises instructions for controlling the second gas source to introduce an effective amount of oxygen into the chamber to modify a process operation.

In a further embodiment, a machine-readable storage medium is also disclosed. The machine-readable storage medium, in one example, contains executable program instructions which, when executed, cause a digital processing system to form a method comprising introducing a liquid via a carrier gas, and separate from the liquid, introducing a first gas and a second gas. The first gas comprises ozone and a legacy amount of oxygen and the second gas comprises an effective amount of oxygen to modify a process operation, such as an etching operation or a film formation operation.

### BRIEF DESCRIPTION OF THE DRAWINGS

FIG. 1 illustrates a schematic view of one embodiment of a wafer processing environment.

FIG. 2 shows a schematic illustration of one embodiment of a gas panel for use in conjunction with the wafer processing environment of FIG. 1.

FIG. 3 shows a schematic illustration of a second embodiment of a gas panel for use in conjunction with the wafer processing environment of FIG. 1.

FIG. 4 shows a schematic illustration of one embodiment of a gas panel for introducing a gas source into the wafer processing environment of FIG. 1.

FIG. 5 shows a schematic top view of one embodiment of a mixing block for use in conjunction with the wafer processing environment of FIG. 1.

FIG. 6 shows one representation of a process flow for forming a film on a substrate.

### DETAILED DESCRIPTION

Disclosed is a method, a system for implementing a method, and a machine-readable storage medium embodying a method of introducing a liquid and a gas into a wafer processing environment. The introduction described, in one embodiment, is in the context of introducing a liquid source with an ozone gas source to form, for example, oxide (e.g., silicon dioxide) films. Suitable films include undoped silicate glass (USG), borosilicate glass (BSG), phosphosilicate glass (PSG), and borophosphosilicate glass (BPSG). In addition to the introduction of ozone in the environment, perhaps with a legacy amount of oxygen, the method and system describe the introduction of supplemental oxygen to improve a process operation, and/or the film characteristics. Such process operation may include a film formation operation or an etch operation.

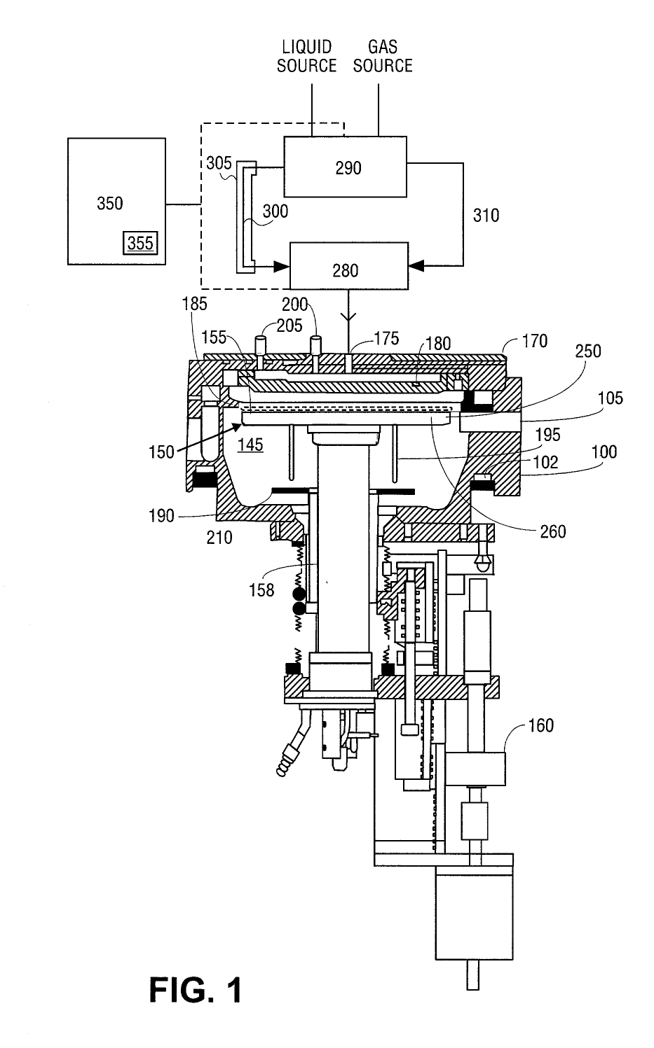

FIG. 1 shows a schematic side view of one embodiment of a wafer processing system. Included in the illustration is a cross-sectional side view of a single-wafer chamber. The single-wafer chamber in the system of FIG. 1 is suitable, for example, in a film-formation process, such as a chemical vapor deposition (CVD) process, including atmospheric CVD (ACVD), sub-atmospheric CVD (SACVD), and low pressure CVD (LPCVD) processes. Suitable single-wafer chambers include, but are not limited to GIGAFILL™ and DXZ™ chambers commercially available from Applied Materials, Inc. of Santa Clara, Calif. A twin chamber such as a PRODUCER™ commercially available from Applied Materials is also a suitable chamber for a processing system adapted to process multiple wafers at a time.

FIG. 1 shows chamber body 100 that defines reaction chamber 145 where the reaction between a process gas or gases and the wafer takes place, e.g., a CVD reaction. In this sense, a process gas or gases include a liquid injected into a carrier gas. Chamber body 100 is constructed, in one embodiment, of aluminum and has passages 102 for water to be pumped therethrough to cool chamber body 100 (e.g., a “cold-wall” reaction chamber). Resident in chamber 145 is resistive heater 150 including, in this view, susceptor 155 supported by shaft 158. In one embodiment, susceptor 155 has a surface area sufficient to support a semiconductor wafer. A cylindrical susceptor having a diameter of approximately 9.33 inches supported by a shaft having a length of approximately 10 inches is suitable to support an eight inch diameter wafer.

Process gas enters otherwise sealed chamber 145 through distribution port 175 in a top surface of chamber lid 170 of chamber body 100. The process gas is distributed throughout chamber 145 by perforated blocker and face plate 180 located, in this view, above resistive heater 150 and coupled to chamber lid 170 inside chamber 145.

A wafer is placed in chamber 145 on susceptor 155 through entry port 105 in a side portion of chamber body 100. To accommodate a wafer for processing, heater 150 is lowered so that the surface of susceptor 155 is below entry port 105. Typically by a robotic transfer mechanism, a wafer is loaded by way of, for example, a transfer blade into chamber 145 onto the superior surface of susceptor 155. Once loaded, entry port 105 is sealed and heater 150 is advanced in a superior (e.g., upward) direction toward face plate 180 by lifter assembly 160 that is, for example, a step motor. The advancement stops when the wafer is a short distance (e.g., 400-700 mils) from blocker and face plate 180. At this point, a process gas or process gases controlled by a gas panel (as described below) flow into chamber 145 through gas distribution port 175, through perforated blocker and face plate 180, and typically react or are deposited on a wafer to form a film. In a pressure controlled system, the pressure in chamber 145 is established and maintained by a pressure regulator or regulators coupled to chamber 145. In one embodiment, for example, the pressure is established and maintained by baratome pressure regulator(s) coupled to chamber body 100 as known in the art.

After processing, residual process gas or gases are pumped from chamber 145 through pumping channel 185 to a collection vessel. Chamber 145 may then be purged, for example, with an inert gas, such as nitrogen. After processing and purging, heater 150 is advanced in an inferior direction (e.g., lowered) by lifter assembly 160. As heater 150 is moved, lift pins 195, having an end extending through openings or throughbores in a surface of susceptor 155 and a second end extending in a cantilevered fashion from an inferior (e.g., lower) surface of susceptor 155, contact lift plate 190 positioned at the base of chamber 145. In one embodiment, at this point, lift plate 190 does not advance from a wafer-load position to a wafer-separate position as does heater 150. Instead, lift plate 190 remains at a reference level on shaft 158. As heater 150 continues to move in an inferior direction through the action of lifter assembly 160, lift pins 195 remain stationary and ultimately extend above the superior or top surface of susceptor 155 to separate a processed wafer from the surface of susceptor 155.

Once a processed wafer is separated from the surface of susceptor 155, a transfer blade of a robotic mechanism is inserted through entry port 105 to a “pick out” position inside chamber 145. The “pick out” position is below the processed wafer. Next, lifter assembly 160 inferiorly moves (e.g., lowers) lift plate 190 to, for example, a second reference level on shaft 158. By moving lift plate 190 in an inferior direction, lift pins 195 are also moved in an inferior direction, until the underside of the processed wafer contacts the transfer blade. The processed wafer is then removed through entry port 105 by, for example, a robotic transfer mechanism that removes the wafer and transfers the wafer to the next processing step. A second wafer may then be loaded into chamber 145. The steps described above are reversed to bring the wafer into a process position. A detailed description of one suitable lifter assembly 160 is described in U.S. Pat. No. 5,772,773, assigned to Applied Materials, Inc., of Santa Clara, Calif.

In high temperature operation, the reaction temperature inside chamber 145 can be as high as 750° C. or more. Accordingly, the exposed components in chamber 145 must be compatible with such high temperature processing. Such materials should also be compatible with the process gases and other chemicals, such as cleaning chemicals, that may be introduced into chamber 145. In one embodiment, exposed surfaces of heater 150 are comprised of aluminum nitride (AIN). For example, susceptor 155 and shaft 158 may be comprised of similar aluminum nitride material. Alternatively, the surface of susceptor 155 may be comprised of high thermally conductive aluminum nitride material (on the order of 95% purity with a thermal conductivity from 140 W/mK to 200 W/mK) while shaft 158 is comprised of a lower thermally conductive aluminum nitride (on the order of 60 W/mK to 100 W/mK). Susceptor 155 of heater 150 is typically bonded to shaft 158 through diffusion bonding or brazing as such coupling will similarly withstand the environment of chamber 145.

Lift pins 195 are also present in chamber 145 during processing. Accordingly, lift pins 195 must be compatible with the operating conditions within chamber 145. A suitable material for lift pins 195 includes, but is not limited to, sapphire or aluminum nitride. A further component that is exposed to the environment of chamber 145 is lift plate 190. Accordingly, in one embodiment, lift plate 190, including a portion of the shaft of lift plate 190, is comprised of an aluminum nitride (e.g., thermally conductive aluminum nitride on the order of 140 W/mK to 200 W/mK) composition.

In addition to the process chamber, FIG. 1 schematically illustrates a gas panel coupled to the process chamber through a mixing block. Referring to FIG. 1, in one embodiment, gas panel 290 regulates the delivery of a gas source and a liquid source to mixing block 280 and then to chamber 145. In a CVD operation to form an oxide film, for example, a liquid source and a gas source may be introduced into chamber 145. In FIG. 1, the liquid source enters mixing block 280 through liquid line 300 while the gas source enters mixing block 280 through gas line 310. Liquid line 300 is shown, in this embodiment, to include heating jacket 305 wrapped around it. Heating jacket 305 may include a filament to heat the liquid source prior to the introduction of the liquid source into mixing block 280. A representative temperature of a liquid source for a CVD oxide deposition process is on the order of 90° to 100° C.

FIG. 1 also shows controller 350 coupled to gas panel 290 and mixing block 280. In one aspect, controller 350 controls the flow of constituents (e.g., liquid(s) and/or gas(es)) to mixing block 280 and chamber 145. Controller 350 is supplied with software instruction logic that is, for example, a computer program stored in a computer readable medium such as memory 355 in controller 350. Memory 355 is, for example, a portion of a hard disk drive. Controller 350 may also be coupled to a user interface that allows an operator to enter the reaction parameters, such as the desired flow rate of process gas or gases and the reaction temperature. In a CVD process, controller 350 may further be coupled to a pressure indicator that measures the pressure in chamber 145 as well as a vacuum source to adjust the pressure in chamber 145.

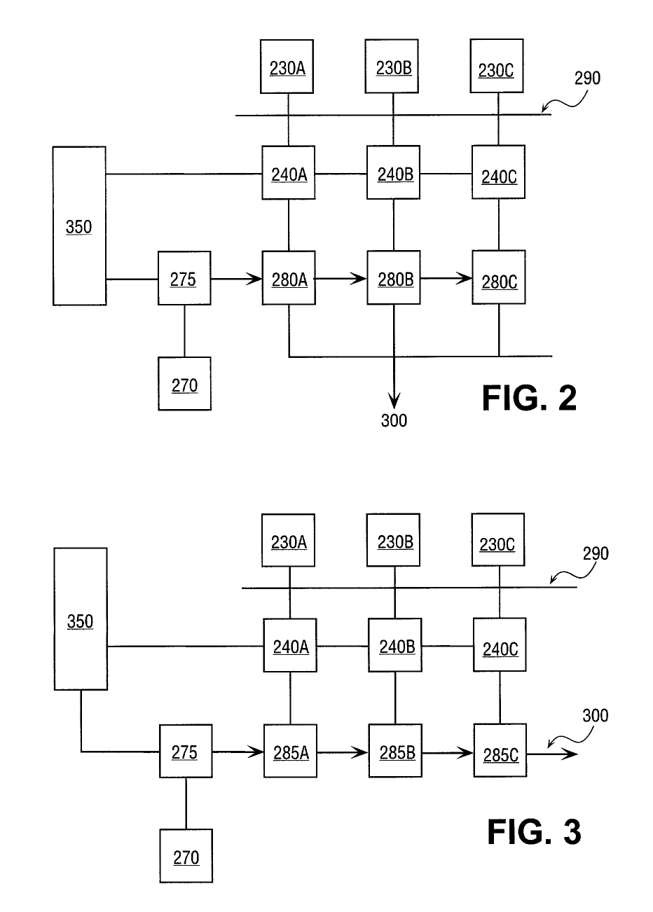

Referring to FIG. 2, the liquid portion of the gas panel is described. In this embodiment, liquid sources 230A, 230B, and 230C are coupled to gas panel 290. Liquid sources 230A, 230B, and 230C may be supply tanks of the desired liquid for a process operation. In terms of a process operation to form an oxide film, the liquid sources are, for example, tetraethylorthosilicate (TEOS), tetraethylboron (TEB), and tetraethylphosphorous (TEP). Within gas panel 290 are liquid flow meters 240A, 240B, and 240C coupled to liquid source 230A, liquid source 230B, and liquid source 230C, respectively. Controller 350 is coupled to liquid flow meter 240A, liquid flow meter 240B, and liquid flow meter 240C to control the introduction of liquid into liquid line 300. In the introduction of one or more liquids from liquid source 230A, liquid source 230B, and liquid source 230C, into liquid line 300, such liquid is aided by a carrier gas of, for example, helium (He), nitrogen (N₂), or He/N₂. Carrier gas from carrier gas source 270 is injected at injection valve 285A, injection valve 285B, and/or injection valve 285C. Controller 350 controls the amount/volume of carrier gas introduced from carrier gas source 270 through mass flow meter 275. Thus, the liquid sources (liquid source 230A, liquid source 230B, and/or liquid source 230C) are injected with carrier gas into liquid line 300 to mixing block 280 (shown in FIG. 1). As illustrated in FIG. 2, the injection of carrier gas into the liquid from liquid sources 230A, 230B, and/or 230C is accomplished in a parallel injection scheme.

As one example of a liquid flow to form an oxide film on a 200 millimeter wafer in a GIGAFILL™ chamber, a liquid flow rate on the order of one to four standard liters per minute (SLM) of, for example, TEOS may be combined with a carrier gas having a flow rate of 8 SLM.

FIG. 3 shows an alternative serial injection of carrier gas from carrier gas source 270 into the liquids from liquid sources 230A, 230B, and 230C. In FIG. 3, like references in FIG. 2 are given similar numeral references. Thus, gas panel 290 includes liquid flow meter 240A, liquid flow meter 240B, and liquid flow meter 240C, respective ones for liquid source 230A, liquid source 230B, and liquid source 230C. Again, each of the liquid flow meters is coupled to controller 350 to control the introduction of liquid from liquid source 230A, liquid source 230B, and/or liquid source 230C.

In FIG. 3, carrier gas from carrier gas source 270 is injected through injection valves 285A, 285B, and/or 285C, in a serial fashion. The carrier gas is first injected into injection valve 285A and, if liquid from liquid source 230A is present, such liquid is carried with carrier gas to injection valve 285B. If liquid from liquid source 230B is introduced at injection valve 285B, the combined carrier gas, liquid from liquid source 230A if present, and liquid from liquid source 230B is carried to injection valve 285C where it may or may not pick up liquid introduced from liquid source 230C. The combination of the carrier gas and liquid from one or more liquid sources is then introduced into liquid line 300.

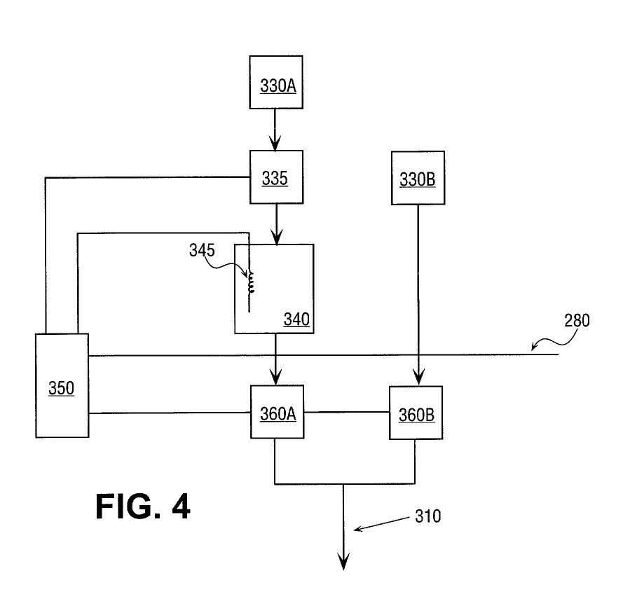

In addition to the liquid in liquid line 300, gas panel 290 also controls the introduction of a separate gas into mixing block 280 through gas line 310. FIG. 4 schematically illustrates one embodiment demonstrating the introduction of a gas or gases into gas line 310. In this embodiment, the gas introduced into gas line 310 includes ozone, a legacy amount of oxygen, and a supplemental amount of oxygen. Referring to FIG. 4, there is shown oxygen source 330A and oxygen source 330B. It is appreciated that the oxygen sources 330A and 330B may be a single oxygen source.

A certain amount of ozone may be desired in the formation of an oxide film in the process as described herein. In this embodiment, oxygen source 330A introduces oxygen into ozonator 340 to form ozone. Oxygen gas from oxygen source 330A is metered into ozonator 340 through mass flow controller 335. Mass flow controller 335 is coupled to controller 350 to control the introduction of oxygen gas into ozonator 340. Ozonator 340 includes energy source 345 (e.g., electrical discharge or ultraviolet light) to energize the oxygen gas and form ozone. The discharge of the ozonator may include ozone and a legacy amount of oxygen. An additional mass flow controller, such as mass flow controller 360A may be included at the discharge of ozonator 340 to control the introduction of the ozone/legacy oxygen into gas line 310. Mass flow controller 360 may be controlled, in this example, by controller 350.

In addition to the ozone and legacy oxygen introduced into gas line 310, FIG. 4 also shows the introduction of a supplemental amount of oxygen into gas line 310. In this example, oxygen gas from oxygen source 330B (which may be the same as oxygen source 330A) is introduced into gas line 310 through mass flow controller 360B within gas panel 290.

In FIG. 4, a separate supplementation of oxygen is described (i.e., through a separate mass flow meter) and combining with ozone and a legacy amount of oxygen in gas line 310. It is appreciated that the supplemental oxygen may also be introduced as a single source from oxygen source 330A into ozonator 340 and, through mass flow controller 360A and into gas line 310. In one instance, an ozonator acts by breaking down oxygen with an energy source. Thus, the introduction of a larger volume of oxygen into ozonator 340 may be controlled such that a similar amount of ozone is produced and the discharge also includes a legacy amount of oxygen as well as the supplemental amount of oxygen.

In one example where five liters of oxygen is introduced into ozonator 340 in connection with the formation of an oxide film, suitable supplementation with additional oxygen from oxygen source 330B may be on the order of one to 10 liters of oxygen and, preferably 2 to 8 liters of oxygen to modify a film formation process.

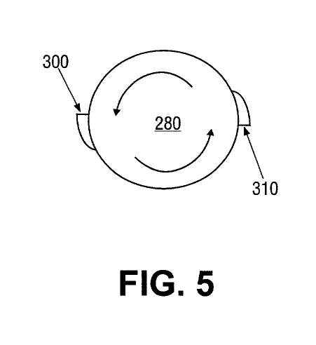

FIG. 5 shows a schematic top view of an embodiment of mixing block 280. In this embodiment, a liquid/carrier gas through liquid line 300 enters a generally cylindrical chamber mixing block 280 at one side and in one direction. An ozone/legacy oxygen and supplemental oxygen through gas line 310 enter the chamber of mixing block 280 in a direction different than the direction for the liquid/carrier gas through liquid line 300. Once in the chamber of mixing block 280, the components from liquid line 300 and gas line 310 mix prior to entering chamber 145 (see FIG. 1). Thus, the mixture of liquid/carrier gas and ozone/legacy oxygen/supplemental oxygen is introduced as a process gas through distribution port 175 and blocker and perforated face plate 180 (FIG. 1). In one regard, it is believed that the supplementation of process gas with oxygen contributes to the mixing of the individual constituents within mixing block 280.

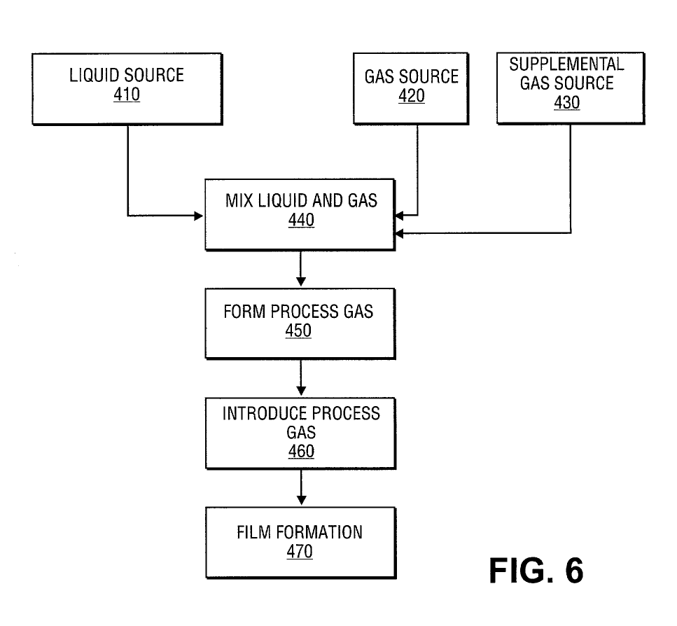

FIG. 6 demonstrates a method of forming a film on a substrate such as a wafer. In one embodiment, the film formation is in the context of a CVD process to form an oxide film on a substrate. It is appreciated that instruction logic embedded in a machine-readable medium stored in a memory of a process controller (e.g., controller 350) may direct the operation of the described method.

Referring to process 400 of FIG. 6, a liquid from a liquid source (block 410) and preferably injected into a carrier gas is introduced into a mixing chamber (e.g., a mixing block). Concurrent with the introduction of a liquid, a gas from a gas source (block 420) is introduced into the mixing chamber. In one embodiment, the gas includes ozone with a legacy amount of oxygen. In addition to the ozone and legacy amount of oxygen, the process is supplemented with an additional amount (volume) of oxygen (block 430). It is appreciated that the ozone/legacy oxygen and supplemental oxygen may be introduced from a single source (e.g., a single oxygen source) or from separate sources (or separate lines from the same source).

Referring to block 440, in the mixing chamber the liquid and gas (ozone/legacy oxygen/supplemental oxygen) are mixed. The mixture represents a process gas (block 450). The process gas is introduced into a process chamber (block 460). According to the process parameters of the chamber, the process gas reacts with and/or combines and/or is deposited as a film on a substrate in the chamber. In terms of a wafer, the film may be introduced (deposited) on a bare substrate or a substrate such as a wafer having one or more device or interconnect levels.

In terms of introducing (depositing) an oxide film, the film characteristics of an undoped silicate glass (USG) were analyzed with and without supplemental oxygen. To form a first USG film on a substrate (e.g., wafer) a liquid (e.g., TEOS) was injected into a carrier gas of helium in a liquid line (e.g., liquid line 300) into mixing block 280. A separate gas source including ozone and legacy oxygen is also introduced through a gas line (e.g., gas line 310) into mixing block 280. The gas source comprised a 5 liter ozone/oxygen mixture of 12.5 percent by weight ozone. The process gas mixture from the mixing block was introduced into a chamber as part of an SACVD process of forming an oxide film.

As a comparison, a second USG film was formed according to an SACVD process on a second substrate (e.g., wafer) according to similar process conditions of temperature and pressure. The process gas utilized to form the second USG film, was supplemented with up to eight liters of oxygen (at gas line 310) so as to increase the volume within the mixing block.

A comparison of the film formation properties of the first USG film and the second USG film showed an increase in the deposition rate of the second film (approximately 50 angstroms per minute (Å/min.) at conventional deposition rates of 800 to 1000 Å/min.). The characteristics of the two films showed the second USG also had improved film uniformity (350 Å range to 100 Å range) and improved gap fill by visual inspection. Film uniformity is represented as a “range uniformity” that examines the maximum and minimum film thickness over a range. A percent uniformity is an average of the range uniformity. For a film thickness on the order of 6000 Å, range uniformity of 350 Å showed a three percent uniformity improvement and a range uniformity of 100 Å showed a 0.8 percent uniformity for oxygen supplemented deposition.

The above-described example related to an SACVD process for forming a USG film. It is appreciated that oxygen supplementation of a process gas may be used in other CVD environments, including ACVD and CPCVD to improve the performance and/or characteristics of films according to such conditions. Under controlled conditions, oxygen supplementation may also be incorporated into high density plasma (HDP) processes to improve the performance and/or characteristics of films formed in this manner.

The above-described SACVD process of forming an oxide film utilizes a carrier gas of helium to deliver an undoped liquid oxide precursor to the mixing block. It is appreciated that oxygen supplementation as described herein is not confined to oxide formation environments utilizing a particular oxide precursor or carrier gas. Similar improved performance and/or characteristics may be achieved with other oxide precursors (TEB, TEP, etc.) and other carrier gases (e.g., nitrogen, helium and nitrogen, etc.)

Various embodiments of a method of oxygen supplementation, a system for oxygen supplementation, and a machine-readable storage medium embodying a method of oxygen supplementation involving microelectronic structure fabrication have been described. In the foregoing specification, the embodiments are described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative rather than a restrictive sense.

What is claimed is:

1. A method comprising:
in a wafer processing environment, introducing a liquid via a carrier gas; and
separate from the liquid, introducing a first gas comprising ozone and a legacy amount of oxygen and a second gas comprising an effective amount of oxygen to modify a process operation.

2. The method of claim 1, wherein introducing the first gas and the second gas further comprises:
forming the first gas; and
after forming the first gas, combining the second gas and the first gas.

3. The method of claim 1, wherein introducing the first gas and the second gas comprises forming the first gas with the legacy amount of oxygen and the second gas.

4. The method of claim 1, wherein the wafer processing environment comprises an etching environment, and the effective amount of the second gas modifies the etch rate of an etch operation.

5. The method of claim 1, wherein the wafer processing environment comprises a film formation environment, and the effective amount of the second gas modifies the film formation.

6. A system comprising:
a chamber;
a liquid source coupled to the chamber;
a first gas source coupled to the chamber;
a second gas source coupled to the chamber;
a controller configured to control the introduction into the chamber of a liquid from the liquid source, a first gas comprising ozone and a legacy amount of oxygen from the first gas source, and a second gas comprising oxygen from the second gas source; and
a memory coupled to the controller comprising a machine-readable medium having a machine-readable program embodied therein for directing operation of the system, the machine-readable program comprising:
instructions for controlling the second gas source to introduce an effective amount of oxygen into the chamber to modify a process operation.

7. The system of claim 6, wherein the first gas and the second gas are introduced through a single line coupled between the first gas source, the second gas source, and the chamber.

8. The system of claim 7, wherein the first gas source and the second gas source comprise a single gas source.

9. A computer readable storage medium containing executable computer program instructions which when executed cause a digital processing system to perform a method comprising:
introducing a liquid via a carrier gas; and
separate from the liquid, introducing a first gas comprising ozone and a legacy amount of oxygen and a second gas comprising an effective amount of oxygen to modify a process operation.

10. The computer readable storage medium of claim 9, wherein introducing the first gas and the second gas further comprises:
forming the first gas; and
after forming the first gas, combining the second gas and the first gas.

11. The computer readable storage medium of claim 9, wherein introducing the first gas and the second gas comprises forming the first gas with the legacy amount of oxygen and the second gas.

12. The computer readable storage medium of claim 9, wherein the wafer processing environment comprises an etching environment, and the effective amount of the second gas modifies the etch rate of an etch operation.

13. The method of claim 9, wherein the wafer processing environment comprises a film formation environment, and the effective amount of the second gas modifies the film formation.
